(19) United States
(12) Patent Application Publication
(10) Pub. No.: US 2024/0312266 A1
(43) Pub. Date: Sep. 19, 2024

(54) METHOD AND APPARATUS FOR CONTROLLING POWER OF AUXILIARY BATTERY FOR USING EXTERNAL ELECTRIC EQUIPMENT

(71) Applicants: Hyundai Motor Company, Seoul (KR); Kia Corporation, Seoul (KR)

(72) Inventors: Myoung Soo PARK, Yongin-si, Gyeonggi-do (KR); Sung Tae KIM, Gwonseon-gu, Suwon-si (KR); Keyng Bin IM, Asan-si, Chungcheongnam-do (KR)

(73) Assignees: Hyundai Motor Company, Seoul (KR); Kia Corporation, Seoul (KR)

(21) Appl. No.: 18/441,394

(22) Filed: Feb. 14, 2024

(30) Foreign Application Priority Data
Mar. 17, 2023 (KR) 10-2023-0035033

(51) Int. Cl. G07C 5/08; B60R 16/033; G01R 31/3832

(52) U.S. Cl. CPC G07C 5/0816; B60R 16/033; G01R 31/3832

(57) ABSTRACT

In an auxiliary battery power control apparatus and method to use external electrical equipment during parking, the auxiliary battery power control apparatus includes a usage condition setting unit configured to receive and store usage condition information related to use of an auxiliary battery of a vehicle. The auxiliary battery power control apparatus further includes a usage state determining unit configured to detect an available power capacity of the auxiliary battery and generate auxiliary battery usage state information for an external electronic device according to the usage condition information and the available power capacity, when the external electronic device is connected to the auxiliary battery. The auxiliary battery power control apparatus further includes a notification message providing unit configured to provide a notification message to a driver of the vehicle according to the auxiliary battery usage state information.

### CROSS REFERENCE TO RELATED APPLICATION

The present application claims priority to Korean Patent Application No. 10-2023-0035033, filed Mar. 17, 2023, the entire contents of which is incorporated herein for all purposes by this reference.

### BACKGROUND OF THE PRESENT DISCLOSURE

### Field of the Present Disclosure

The present disclosure relates to an auxiliary battery power control apparatus and method to use external electrical equipment during parking.

### Description of Related Art

The statements in the present section merely provide background information related to the present disclosure and do not necessarily form related art.

Conventionally, for use of external electrical equipment in a vehicle, a power outlet and a universal serial bus (USB) port of the vehicle are used.

To use the external electrical equipment in the vehicle, the vehicle needs to be in an ACC or further power state. That is, the ACC or further state means that the power of the vehicle becomes available by switching the vehicle to the ACC state to start the vehicle or causing the vehicle to enter an ON state or a start state.

In a power state of ACC or further, another controller in the vehicle is in a wake-up state, such that when external electrical equipment is used in the power state of ACC or Furthermore, unnecessary discharge occurs due to consumed current of the other controller, negatively affecting performance and durability of a 12V main battery.

The information included in this Background in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an auxiliary battery power control apparatus and method to use external electrical equipment during parking.

Objects to be solved by the present disclosure are not limited to the aforementioned problems, and other unmentioned objects would be apparent to one of ordinary skill in the art from the following description.

According to an aspect of the present disclosure, an auxiliary battery power control apparatus is presented. The apparatus includes a usage condition setting unit configured to receive and store usage condition information related to use of an auxiliary battery of a vehicle. The apparatus further includes a usage state determining unit configured to detect an available power capacity of the auxiliary battery and generate auxiliary battery usage state information for an external electronic device according to the usage condition information and the available power capacity, when the external electronic device is connected to the auxiliary battery. The apparatus further includes a notification message providing unit configured to provide a notification message to a driver of the vehicle according to the auxiliary battery usage state information.

According to an aspect of the present disclosure, an auxiliary battery power control method is presented. The method includes receiving and storing usage condition information related to use of an auxiliary battery of a vehicle. The method further includes detecting an available power capacity of the auxiliary battery and generating auxiliary battery usage state information for an external electronic device according to the usage condition information and the available power capacity, when the external electronic device is connected to the auxiliary battery. The method further includes providing a notification message to a driver of the vehicle according to the auxiliary battery usage state information.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a diagram showing a vehicle system including an auxiliary battery power control apparatus and method, according to an exemplary embodiment of the present disclosure;

FIG. 2 is an example functional block diagram of an auxiliary battery power control apparatus according to the exemplary embodiment of the present disclosure;

FIG. 3A and FIG. 3B are views showing a screen for setting usage condition information for an auxiliary battery;

FIG. 4 is a flowchart illustrating an auxiliary battery power control method according to various exemplary embodiments; and

FIG. 5 is a flowchart illustrating an auxiliary battery power control method according to various exemplary embodiments of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, some exemplary embodiments of the present disclosure will be described in detail with reference to the accompanying drawings. In the following description, like reference numerals designate like elements, although the elements are shown in different drawings. Furthermore, in the following description of various exemplary embodiments of the present disclosure, a detailed description of known functions and configurations incorporated therein will be omitted for clarity and for brevity.

Additionally, various terms such as first, second, A, B, (a), (b), etc., are used solely to differentiate one component from the other but not to imply or suggest the substances, order, or sequence of the components. Throughout the present specification, when a portion ‘includes’ or ‘comprises’ a component, the portion is meant to further include other components, not to exclude thereof unless stated to the contrary. The terms such as ‘unit’, ‘module’, and the like refer to one or more units for processing at least one function or operation, which may be implemented by hardware, software, or a combination thereof.

The detailed description, which will be provided below with reference to the accompanying drawings, is directed to explain exemplary embodiments of the present disclosure, rather than to show the only embodiments which may be implemented according to an exemplary embodiment of the present disclosure.

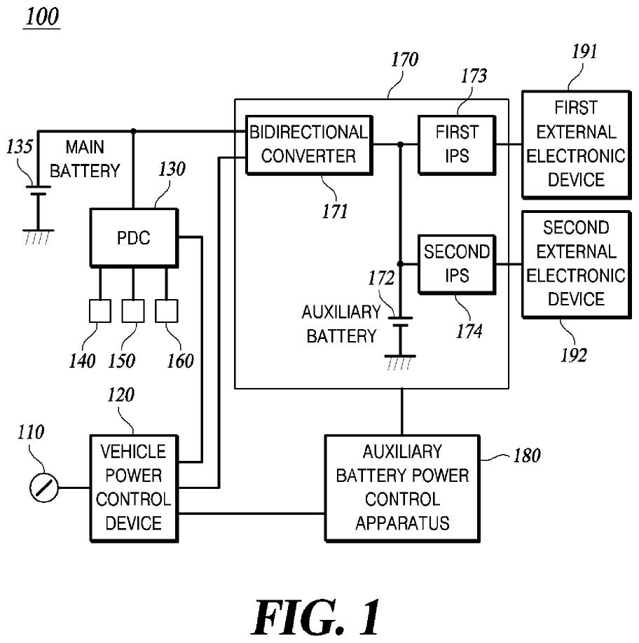

FIG. 1 is a diagram showing a vehicle system including an auxiliary battery power control apparatus, according to an exemplary embodiment of the present disclosure.

As shown in FIG. 1, a vehicle system 100 may include an ignition key 110, a vehicle power control device 120, a power distribution controller (PDC) 130, a main battery 135, a first in-vehicle electronic device 140, a second in-vehicle electronic device 150, a third in-vehicle electronic device 160, an auxiliary battery system 170, and an auxiliary battery power control apparatus 180 according to the exemplary embodiment of the present disclosure.

The auxiliary battery system 170 may include a bidirectional converter 171, an auxiliary battery 172, a first intelligent power switch (IPS) 173, and a second IPS 174. Herein, a lithium battery module for power assistance (a parking lithium battery module (P-LBM)) may be used as the auxiliary battery system 170.

The bidirectional converter 171 may have one end connected to an output terminal of the main battery 135 and the other end connected to an output terminal of the auxiliary battery 172, and may be controlled by the vehicle power control device 120.

The first IPS 173 and the second IPS 174 may be connected in parallel to the output terminal of the auxiliary battery 172 to be respectively connected to external electronic devices 191 and 192. The first IPS 173 may detect current flowing from the auxiliary battery 172 to the first external electronic device 191, and the second IPS 174 may detect current flowing from the auxiliary battery 172 to the second external electronic device 192.

Herein, the external electronic device may be an electronic device such as a universal serial bus (USB) included in the auxiliary battery system 170, a mobile phone connectable to a connection terminal such as an alternating current (AC) terminal, etc., a charging battery, a laptop computer, etc.

Other detailed functions of the bidirectional converter 171, the first IPS 173, and the second IPS 174 fall beyond the subject matter of the present disclosure and thus will not be further described.

According to a start position of the ignition key 110 of the vehicle, the PDC 130 and the auxiliary battery system 170 may be controlled by the vehicle power control device 120.

A power supply line may be connected between the main battery 135 and the bidirectional converter 171, and the PDC 130 may be connected to the power supply line. Thus, at least one of the output terminal of the main battery 135 and the output terminal of the auxiliary battery 172 may be connected to the PDC 130 through the power supply line.

The vehicle power control device 120 may be configured for controlling the PDC 130 according to the start position of the ignition key 110 to determine an in-vehicle electronic device (i.e., the first in-vehicle electronic device 140, the second in-vehicle electronic device 150, the third in-vehicle electronic device 160) supplied with power through the power supply line, according to the start position of the ignition key 110.

When the ignition key 110 is in an OFF state, i.e., the vehicle is in a parking state, the vehicle power control device 120 may be configured for controlling the bidirectional converter 171 to block bidirectional power connection between the auxiliary battery 172 and the main battery 135.

When the ignition key 110 is in the OFF state, the vehicle power control device 120 may be configured for controlling the PDC 130 to supply a power to the first in-vehicle electronic device 140 such as indoor light, emergency light, etc., from a constant power of the main battery 135.

When the ignition key 110 is in an ACC state, the vehicle power control device 120 may be configured for controlling the bidirectional converter 171 to enable bidirectional power connection between the auxiliary battery 172 and the main battery 135.

When the ignition key 110 is in the ACC state, the vehicle power control device 120 may be configured for controlling the PDC 130 to supply a power to the first in-vehicle electronic device 140 and the second in-vehicle electronic device 150 connected to the USB, a power outlet, etc., from the main battery 135 through the power supply line.

When the ignition key 110 is in an ON state, the vehicle power control device 120 may be configured for controlling the bidirectional converter 171 to enable bidirectional power connection between the auxiliary battery 172 and the main battery 135.

When the ignition key 110 is in a start ON state, the vehicle power control device 120 may be configured for controlling the PDC 130 to supply a power to the first in-vehicle electronic device 140, the second in-vehicle electronic device 150, and the third in-vehicle electronic device 160 such as a dashboard, etc., from the main battery 135.

According to an exemplary embodiment of the present disclosure, each of the vehicle power control device 120, the power distribution controller (PDC) 130, and the auxiliary battery power control apparatus 180 may be implemented by a processor (e.g., computer, microprocessor, CPU. ASIC, circuitry, logic circuits, etc.). Each of the vehicle power control device 120, the power distribution controller (PDC) 130, and the auxiliary battery power control apparatus 180 may be implemented by a non-transitory memory storing. e.g., a program(s), software instructions reproducing algorithms, etc., which, when executed, controls operations of various components of the vehicle, and a processor configured to execute the program(s), software instructions reproducing algorithms, etc. Alternatively, the vehicle power control device 120, the power distribution controller (PDC) 130, and the auxiliary battery power control apparatus 180 may be integrated in a single processor.

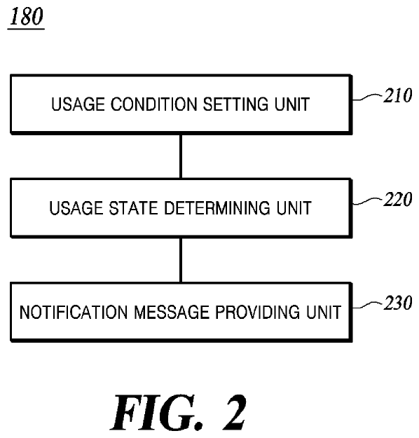

FIG. 2 is an example functional block diagram of the auxiliary battery power control apparatus 180 according to the exemplary embodiment of the present disclosure.

The auxiliary battery power control apparatus 180 according to the exemplary embodiment of the present disclosure may be implemented by including a usage condition setting unit 210, a usage state determining unit 220, and a notification message providing unit 230.

The usage condition setting unit 210 may receive usage condition information related to usage of the auxiliary battery 172 of the vehicle.

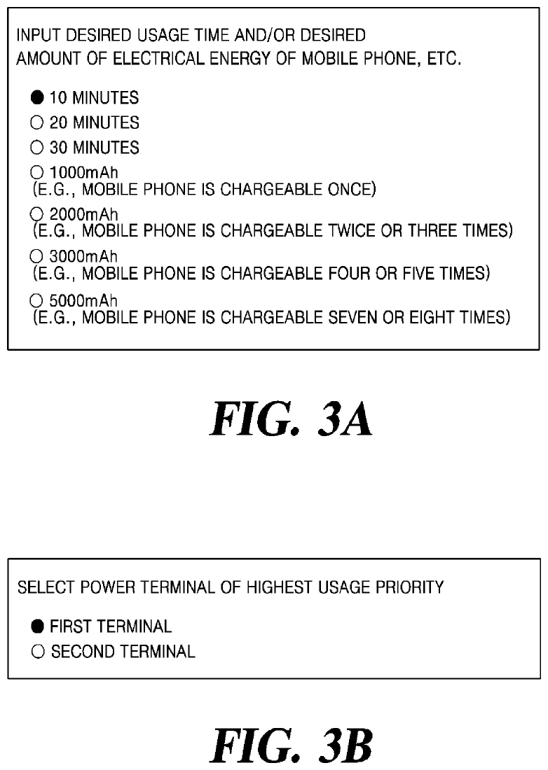

FIG. 3A and FIG. 3B are views showing a screen for setting usage condition information for the auxiliary battery 172.

As shown in FIG. 3A, the auxiliary battery power control apparatus 180 may display a plurality of driver selection items regarding a target usage time (e.g., in units of minutes or hours) and a target amount of electrical energy (e.g., in units of mAh or Wh) by use of a user setting mode (USM) setting device of audio video navigation (AVN) in a vehicle. Depending on an exemplary embodiment of the present disclosure, a selection item regarding several values of target usage times may be displayed or a selection item regarding several values of target amount of electrical energy may be displayed.

When a driver selects one of a plurality of displayed selection items by use of the USM setting device, the usage condition setting unit 210 may receive the selected item as usage condition information for the auxiliary battery 172 of the vehicle.

When the first external electronic device 191 is connected to the auxiliary battery 172, the auxiliary battery 172 may supply a current to the first external electronic device 191 via the first IPS 173.

The usage state determining unit 220 may detect an available power capacity of the auxiliary battery 172 and determine an auxiliary battery usage state regarding the first external electronic device 191 according to the usage condition information and the available power capacity.

When the usage condition information is information related to the target usage time of the auxiliary battery 172, the usage state determining unit 220 may detect a current value flowing from the auxiliary battery 172 to the first external electronic device 191 and multiply the current value by the target usage time to determine an expected amount of electrical energy of the first external electronic device 191. The current value flowing from the auxiliary battery 172 to the first external electronic device 191 may be received from the first IPS 173 to which the first external electronic device 191 is connected.

In the instant case, the usage state determining unit 220 may compare the expected amount of electrical energy with the available power capacity of the auxiliary battery 172 to generate information indicating whether the first external electronic device 191 is available as auxiliary battery usage state information.

For example, when the target usage time is selected as “10 minutes”, for a first current value of 3 A flowing to the first external electronic device 191, the usage state determining unit 220 may multiply the first current value by the target usage time to determine the expected amount of electrical energy of the first external electronic device 191 as 500 mAh.

The usage state determining unit 220 may also compare the expected amount of electrical energy of the first external electronic device 191 with the available power capacity of the auxiliary battery 172 to generate information indicating whether the first external electronic device 191 is available as usage state information. For example, when the available power capacity of the auxiliary battery 172 is greater than or equal to 500 mAh, the usage state determining unit 220 may be configured to determine that the first external electronic device 191 is available for the target usage time. In the instant case, the notification message providing unit 230 may transmit a corresponding notification message to the USM setting device to display a notification message indicating that the first external electronic device 191 is available for the target usage time.

When the available power capacity of the auxiliary battery 172 is less than 500 mAh, the usage state determining unit 220 may be configured to determine that the first external electronic device 191 is not available for the target usage time. In the instant case, the notification message providing unit 230 may transmit a corresponding notification message to the USM setting device to display a notification message indicating that the first external electronic device 191 is available for a time less than the target usage time.

For example, when the available power capacity is 300 mAh, for a first current of 3 A of the first external electronic device 191, the notification message providing unit 230 may divide the available power capacity by the first current to determine an available time as 6 minutes and provide a notification message indicating that the first external electronic device 191 is available for 6 minutes through the notification message providing unit 230.

When the usage condition information is information related to the target amount of electrical energy for the auxiliary battery 172, the usage state determining unit 220 may detect the available power capacity of the auxiliary battery 172 and compare the target amount of electrical energy with the available power capacity to generate information indicating whether the first external electronic device 191 as usage state information of the auxiliary battery 172.

When the available power capacity is greater than or equal to the target amount of electrical energy, the usage state determining unit 220 may be configured to generate information indicating that the first external electronic device 191 is available as much as the target amount of electrical energy, as the usage state information. In the instant case, the notification message providing unit 230 may transmit a corresponding notification message to the USM setting device to display a notification message indicating that the first external electronic device 191 is available as much as the target amount of electrical energy.

For example, when “1000 mAh” is selected as the target amount of electrical energy and the available power capacity of the auxiliary battery 172 is 2000 mAh, the usage state determining unit 220 may be configured to determine that the first external electronic device 191 is available as much as the target amount of electrical energy. In the instant case, the notification message providing unit 230 may transmit a corresponding notification message to the USM setting device to display a notification message indicating that the first external electronic device 191 is available as much as the target amount of electrical energy.

The usage state determining unit 220 may detect the first current value flowing from the auxiliary battery 172 to the first external electronic device 191 and further generate information related to a chargeable time as the usage state information of the auxiliary battery 172 according to the detected first current value.

When “1000 mAh” is selected as the target amount of electrical energy, the available power capacity of the auxiliary battery 172 is 2000 mAh, and the first current value flowing to the first external electronic device 191 is 3 A, the usage state determining unit 220 may divide the target amount of electrical energy by the first current value to determine a time for use as much as the target amount of electrical energy as 20 minutes. In the instant case, the notification message providing unit 230 may transmit a corresponding notification message to the USM setting device to further display a notification message indicating that the target amount of electrical energy is available for the corresponding time of 20 minutes.

Meanwhile, when the available power capacity is less than the target amount of electrical energy, the usage state determining unit 220 may be configured to generate information indicating that the first external electronic device 191 is available by less than the target amount of electrical energy, as the usage state information. In the instant case, the notification message providing unit 230 may transmit a corresponding notification message to the USM setting device to display a notification message indicating that the first external electronic device 191 is available by less than the target amount of electrical energy.

When “1000 mAh” is selected as the target amount of electrical energy and the available power capacity of the auxiliary battery 172 is 500 mAh, the usage state determining unit 220 may be configured to determine that the first external electronic device 191 is available by less than the target amount of electrical energy. In the instant case, the notification message providing unit 230 may transmit a corresponding notification message to the USM setting device to display a notification message indicating that the first external electronic device 191 is available by less than the target amount of electrical energy.

In the instant case, the usage state determining unit 220 may detect the current value flowing from the auxiliary battery 172 to the first external electronic device 191 and generate information related to a chargeable time as the usage state information of the auxiliary battery 172 according to the detected current value.

For example, when “1000 mAh” is selected as the target amount of electrical energy, the available power capacity of the auxiliary battery 172 is 500 mAh, and the first current value flowing to the first external electronic device 191 is 3 A, the usage state determining unit 220 may divide the available power capacity by the first current value to determine a time for use as much as the available power capacity as 10 minutes. In the instant case, the notification message providing unit 230 may transmit a corresponding notification message to the USM setting device to further display a notification message indicating that the available power capacity is available for the corresponding time of 10 minutes.

Meanwhile, when the vehicle enters a start OFF state and thus the power of the auxiliary battery 172 is not supplied to an internal electronic device of the vehicle, then the usage state determining unit 220 may be configured to determine the usage state information.

As shown in FIG. 3B, when a plurality of external electronic devices including the first external electronic device 191 and the second external electronic device 192 are connectable to the auxiliary battery 172, the auxiliary battery power control apparatus 180 may be implemented to select a priority for the first external electronic device 191 and the second external electronic device 192 by use of the USM setting device in the vehicle.

While it is described in the current embodiment that two external electronic devices are connectable, more than two external electronic devices may be connectable to the auxiliary battery 172 depending on an exemplary embodiment of the present disclosure.

As shown in FIG. 3B, when a higher priority is selected for any one external electronic device (e.g., the first external electronic device 191), usage condition information for the auxiliary battery 172 may include priority information for the first external electronic device 191 and the second external electronic device 192. That is, when the higher priority is selected for the first external electronic device 191, then the usage condition setting unit 210 may set, as the usage condition information, information indicating that the first external electronic device 191 includes the higher priority.

Depending on an exemplary embodiment of the present disclosure, an external electronic device first connected to the auxiliary battery 172 may be determined as the external electronic device including the higher priority than the external electronic device connected later, and thus corresponding priority information may be set as the usage condition information. In the instant case, a process of setting the target usage time and/or the target amount of electrical energy shown in FIG. 3A may be a setting process for the external electronic device including the highest priority.

Hereinafter, a description will be made assuming that the first external electronic device 191 includes the higher priority and the second external electronic device 192 includes the lower priority.

When the first external electronic device 191 including the higher priority and the second external electronic device 192 including the lower priority are connected to the auxiliary battery 172 together, the usage state determining unit 220 may be configured to generate usage state information related to the second external electronic device 192 or the first external electronic device 191 according to an expected power consumption of the second external electronic device 192.

When the target usage time is set, the usage state determining unit 220 may detect a first current flowing to the first external electronic device 191 and a second current flowing to the second external electronic device 192 and sum the first current and the second current to determine a summed current.

The usage state determining unit 220 may be configured to determine a first expected amount of electrical energy for the target usage time for which the first external electronic device 191 is available for the first current and determine a summed expected amount of electrical energy for the target usage time with respect to the summed current.

When the available power capacity of the auxiliary battery 172 is greater than or equal to the summed expected amount of electrical energy, then the usage state determining unit 220 may not generate additional usage state information.

When the available power capacity of the auxiliary battery 172 is less than the summed expected amount of electrical energy and is greater than or equal to the first expected amount of electrical energy, the usage state determining unit 220 may be configured to generate the usage state information indicating that difficulty in power supply to the first external electronic device 191 for the target usage time due to connection of the second external electronic device 192. In the instant case, the notification message providing unit 230 may transmit a corresponding notification message to the USM setting device to further display a notification message indicating corresponding usage state information.

When the available power capacity of the auxiliary battery 172 is less than the first expected amount of electrical energy, the usage state determining unit 220 may be configured to generate the usage state information indicating that disconnection of the second external electronic device 192 is required.

When the target amount of electrical energy is set, the usage state determining unit 220 may detect the first current flowing to the first external electronic device 191 and the second current flowing to the second external electronic device 192 and sum the first current and the second current to determine the summed current.

The usage state determining unit 220 may be configured to determine a sum target amount of electrical energy by determining a target amount of electrical energy*[summed current/first current].

When the available power capacity of the auxiliary battery 172 is greater than or equal to the sum target amount of electrical energy, then the usage state determining unit 220 may not generate additional usage state information.

When the available power capacity of the auxiliary battery 172 is less than the sum target amount of electrical energy and is greater than or equal to the target amount of electrical energy, the usage state determining unit 220 may be configured to generate the usage state information indicating that difficulty in supplying the target amount of electrical energy to the first external electronic device 191 due to connection of the second external electronic device 192. In the instant case, the notification message providing unit 230 may transmit a corresponding notification message to the USM setting device to further display a notification message indicating corresponding usage state information.

When the available power capacity of the auxiliary battery 172 is less than the target amount of electrical energy, the usage state determining unit 220 may be configured to generate the usage state information indicating that disconnection of the second external electronic device 192 is required.

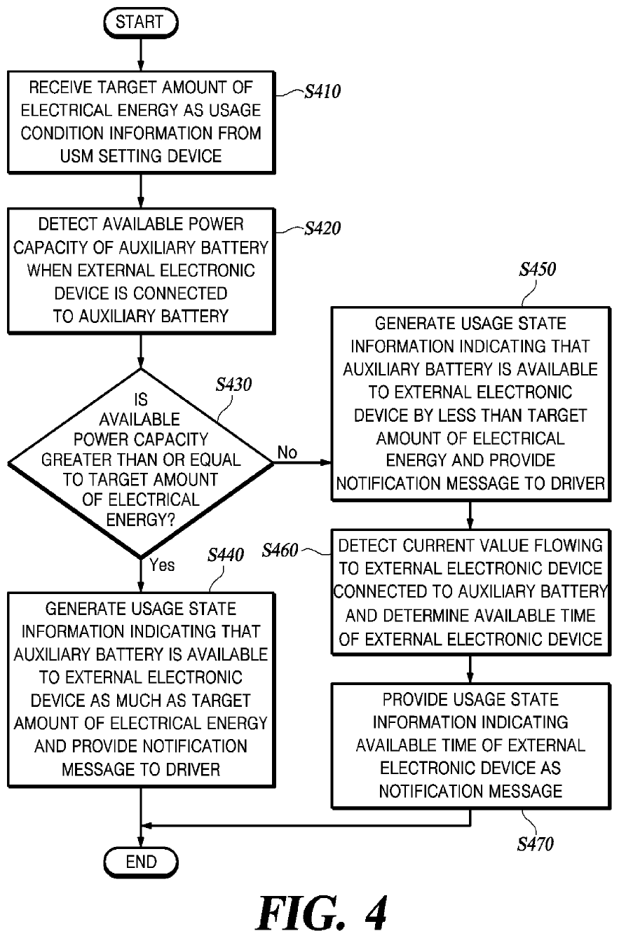

FIG. 4 is a flowchart illustrating an auxiliary battery power control method according to various exemplary embodiments of the present disclosure.

Hereinafter, a description will include an auxiliary battery power control method according to the various exemplary embodiments with reference to FIGS. 1 to 4 together.

The auxiliary battery power control method according to the various exemplary embodiments are an exemplary embodiment for a case where a target amount of electrical energy is set as usage condition information.

The usage condition setting unit 210 may receive a target amount of electrical energy as the usage condition information from a USM setting device, in operation S410.

When the external electronic device is connected to the auxiliary battery 172, the usage state determining unit 220 may detect an available power capacity of the auxiliary battery 172 in operation S420.

The usage state determining unit 220 may be configured to determine whether the available power capacity is greater than or equal to the target amount of electrical energy, in operation S430.

When the available power capacity is greater than or equal to the target amount of electrical energy, the usage state determining unit 220 may be configured to generate usage state information indicating that the auxiliary battery 172 is available to the external electronic device as much as the target amount of electrical energy and the notification message providing unit 230 may provide a notification message to a driver of the vehicle according to the usage state information, in operation S440.

When the available power capacity is less than the target amount of electrical energy, the usage state determining unit 220 may be configured to generate usage state information indicating that the auxiliary battery 172 is available to the external electronic device by less than the target amount of electrical energy and the notification message providing unit 230 may provide a notification message to a driver of the vehicle according to the usage state information, in operation S450.

The usage state determining unit 220 may detect a current value flowing to an external electronic device connected to the auxiliary battery 172 and determine an available time of the external electronic device, in operation S460.

The notification message providing unit 230 may provide, as the notification message, the usage state information indicating an available time of the external electronic device, in operation S470.

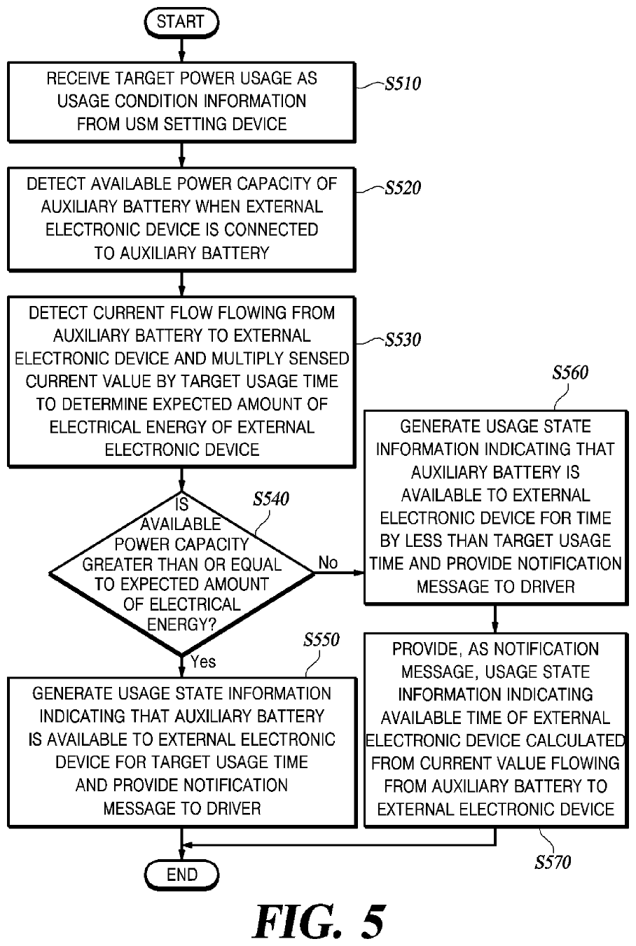

FIG. 5 is a flowchart illustrating an auxiliary battery power control method according to various exemplary embodiments of the present disclosure.

Hereinafter, a description will include an auxiliary battery power control method according to the various exemplary embodiments with reference to FIGS. 1 to 3 and 5 together.

The auxiliary battery power control method according to the various exemplary embodiments are an exemplary embodiment for a case where a target usage time is set as usage condition information.

The usage condition setting unit 210 may receive a target usage time as the usage condition information from a USM setting device, in operation S510.

When the external electronic device is connected to the auxiliary battery 172, the usage state determining unit 220 may detect an available power capacity of the auxiliary battery 172 in operation S520.

The usage state determining unit 220 may detect a current value flowing to an external electronic device from the auxiliary battery 172 and multiply the detected current value by the target usage time to determine an expected amount of electrical energy of the external electronic device, in operation S530.

The usage state determining unit 220 may be configured to determine whether the available power capacity is greater than or equal to the expected amount of electrical energy, in operation S540.

When the available power capacity is greater than or equal to the expected amount of electrical energy, the usage state determining unit 220 may be configured to generate usage state information indicating that the auxiliary battery 172 is available to the external electronic device for the target usage time and the notification message providing unit 230 may provide a notification message to a driver of the vehicle according to the usage state information, in operation S550.

When the available power capacity is less than the expected amount of electrical energy, the usage state determining unit 220 may be configured to generate usage state information indicating that the auxiliary battery 172 is available to the external electronic device for a time less than the target usage time and the notification message providing unit 230 may provide a notification message to a driver of the vehicle according to the usage state information, in operation S560.

The usage state determining unit 220 may be configured to determine the available time of the external electronic device from the current value flowing to the external electronic device from the auxiliary battery 172, and provide, as the notification message, the usage state information indicating the available time of the external electronic device, in operation S570.

According to an exemplary embodiment of the present disclosure, by inputting a usage time of and the number of times of use of a mobile phone, etc., and a target usage power and a target usage time of an external electronic device, a user-target amount of electrical energy may be set.

When a target amount of electrical energy of the external electronic device is greater than an available power capacity of the auxiliary battery, a notification may be provided to a driver.

When the available power capacity is less than the target amount of electrical energy, an insufficient power capacity may be determined and provided to the driver.

Effects of the present disclosure are not limited to the aforementioned effects, and other unmentioned effects would be apparent to one of ordinary skill in the art from the above disclosure.

Each element of the apparatus or method in accordance with various aspects of the present disclosure may be implemented in hardware or software, or a combination of hardware and software. The functions of the respective elements may be implemented in software, and a microprocessor may be implemented to execute the software functions corresponding to the respective elements.

Various embodiments of systems and techniques described herein may be realized with digital electronic circuits, integrated circuits, field programmable gate arrays (FPGAs), application specific integrated circuits (ASICs), computer hardware, firmware, software, and/or combinations thereof. The various embodiments may include implementation with one or more computer programs that are executable on a programmable system. The programmable system includes at least one programmable processor, which may be a special purpose processor or a general purpose processor, coupled to receive and transmit data and instructions from and to a storage system, at least one input device, and at least one output device. Computer programs (also known as programs, software, software applications, or code) include instructions for a programmable processor and are stored in a “computer-readable recording medium.”

The computer-readable recording medium may include all types of storage devices on which computer-readable data can be stored. The computer-readable recording medium may be a non-volatile or non-transitory medium such as a read-only memory (ROM), a random access memory (RAM), a compact disc ROM (CD-ROM), magnetic tape, a floppy disk, or an optical data storage device. In addition, the computer-readable recording medium may further include a transitory medium such as a data transmission medium. Furthermore, the computer-readable recording medium may be distributed over computer systems connected through a network, and computer-readable program code can be stored and executed in a distributive manner.

Although operations are illustrated in the flowcharts/timing charts in the present specification as being sequentially performed, this is merely an exemplary description of the technical idea of an exemplary embodiment of the present disclosure. In other words, those skilled in the art to which an exemplary embodiment of the present disclosure belongs may appreciate that various modifications and changes may be made without departing from essential features of an exemplary embodiment of the present disclosure, that is, the sequence illustrated in the flowcharts/timing charts may be changed and one or more operations of the operations may be performed in parallel. Thus, flowcharts/timing charts are not limited to the temporal order.

Furthermore, the term related to a control device such as “controller”, “control apparatus”, “control unit”, “control device”, “control module”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may be configured to process data according to a program provided from the memory, and may be configured to generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the memory and the processor may be provided as one chip, or provided as separate chips.

In various exemplary embodiments of the present disclosure, the scope of the present disclosure includes software or machine-executable commands (e.g., an operating system, an application, firmware, a program, etc.) for enabling operations according to the methods of various embodiments to be executed on an apparatus or a computer, a non-transitory computer-readable medium including such software or commands stored thereon and executable on the apparatus or the computer.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

In an exemplary embodiment of the present disclosure, the vehicle may be referred to as being based on a concept including various means of transportation. In some cases, the vehicle may be interpreted as being based on a concept including not only various means of land transportation, such as cars, motorcycles, trucks, and buses, that drive on roads but also various means of transportation such as airplanes, drones, ships, etc.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of at least one of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

According to an exemplary embodiment of the present disclosure, components may be combined with each other to be implemented as one, or some components may be omitted.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. An auxiliary battery power control apparatus comprising:
a usage condition setting unit configured to receive and store usage condition information related to use of an auxiliary battery of a vehicle;
a usage state determining unit configured to detect an available power capacity of the auxiliary battery and generate auxiliary battery usage state information for an external electronic device according to the usage condition information and the available power capacity, in response that the external electronic device is connected to the auxiliary battery; and
a notification message providing unit configured to provide a notification message to a driver of the vehicle according to the auxiliary battery usage state information.

2. The auxiliary battery power control apparatus of claim 1, wherein the usage state determining unit is further configured to detect a current value flowing from the auxiliary battery to the external electronic device and determine an expected amount of electrical energy of the external electronic device according to the current value and a target usage time, in response that the usage condition information is information related to the target usage time of the auxiliary battery.

3. The auxiliary battery power control apparatus of claim 2, wherein the usage state determining unit is further configured to compare the expected amount of electrical energy with the available power capacity and generate, as the usage state information, information indicating whether the external electronic device is available.

4. The auxiliary battery power control apparatus of claim 1, wherein the usage state determining unit is further configured to compare a target amount of electrical energy of the auxiliary battery with the available power capacity and generate, as the usage state information, information indicating whether the external electronic device is available, in response that the usage condition information is information related to the target amount of electrical energy.

5. The auxiliary battery power control apparatus of claim 4, wherein the usage state determining unit is further configured to detect a current value flowing from the auxiliary battery to the external electronic device and generate information related to a chargeable time as the usage state information according to the current value.

6. The auxiliary battery power control apparatus of claim 1, wherein the usage state determining unit is further configured to determine the usage state information in response that the vehicle enters a start OFF state and thus a power of the auxiliary battery is not supplied to an internal electronic device of the vehicle.

7. The auxiliary battery power control apparatus of claim 1, wherein, in response that a plurality of external electronic devices including a first electronic device and a second electronic device are connectable to the auxiliary battery, the usage condition information includes priority information related to the first electronic device and the second electronic device.

8. The auxiliary battery power control apparatus of claim 7, wherein the usage state determining unit is further configured to generate usage state information related to an external electronic device of a lower priority based on a power consumption of the external electronic device of the lower priority between the first electronic device and the second electronic device.

9. The auxiliary battery power control apparatus of claim 8, wherein the usage state determining unit is further configured to determine a summed current of a first current flowing from the auxiliary battery to the first electronic device and a second current flowing from the auxiliary battery to the second electronic device and generate the usage state information related to the external electronic device of the lower priority based on the first current and the summed current.

10. A method of controlling auxiliary battery power, the method comprising:
receiving and storing, by a processor, usage condition information related to use of an auxiliary battery of a vehicle;
detecting, by the processor, an available power capacity of the auxiliary battery and generating auxiliary battery usage state information for an external electronic device according to the usage condition information and the available power capacity, in response that the external electronic device is connected to the auxiliary battery; and
providing, by the processor, a notification message to a driver of the vehicle according to the auxiliary battery usage state information.

11. The method of claim 10, wherein the processor is further configured to detect a current value flowing from the auxiliary battery to the external electronic device and determine an expected amount of electrical energy of the external electronic device according to the current value and a target usage time, in response that the usage condition information is information related to the target usage time of the auxiliary battery.

12. The method of claim 11, wherein the processor is further configured to compare the expected amount of electrical energy with the available power capacity and generate, as the usage state information, information indicating whether the external electronic device is available.

13. The method of claim 10, wherein the processor is further configured to compare a target amount of electrical energy of the auxiliary battery with the available power capacity and generate, as the usage state information, information indicating whether the external electronic device is available, in response that the usage condition information is information related to the target amount of electrical energy.

14. The method of claim 13, wherein the processor is further configured to detect a current value flowing from the auxiliary battery to the external electronic device and generate information related to a chargeable time as the usage state information according to the current value.

15. The method of claim 10, wherein the processor is further configured to determine the usage state information in response that the vehicle enters a start OFF state and thus a power of the auxiliary battery is not supplied to an internal electronic device of the vehicle.

16. The method of claim 10, wherein, in response that a plurality of external electronic devices including a first electronic device and a second electronic device are connectable to the auxiliary battery, the usage condition information includes priority information related to the first electronic device and the second electronic device.

17. The method of claim 16, wherein the processor is further configured to generate usage state information related to an external electronic device of a lower priority based on a power consumption of the external electronic device of the lower priority between the first electronic device and the second electronic device.

18. The method of claim 17, wherein the processor is further configured to determine a summed current of a first current flowing from the auxiliary battery to the first electronic device and a second current flowing from the auxiliary battery to the second electronic device and generate the usage state information related to the external electronic device of the lower priority based on the first current and the summed current.

19. A non-transitory computer-readable recording medium in which a program for executing a method of controlling auxiliary battery power is recorded, the recording medium storing the program to implement:
receiving and storing usage condition information related to use of an auxiliary battery of a vehicle;
detecting an available power capacity of the auxiliary battery and generating auxiliary battery usage state information for an external electronic device according to the usage condition information and the available power capacity, in response that the external electronic device is connected to the auxiliary battery; and
providing a notification message to a driver of the vehicle according to the auxiliary battery usage state information.
